(19) United States
(12) Patent Application Publication
(10) Pub. No.: US 2011/0192461 A1
(43) Pub. Date: Aug. 11, 2011

(54) Zone Melt Recrystallization of layers of polycrystalline silicon

(75) Inventors: Larry Hendler, San Jose, CA (US); Sharone Zehavi, San Jose, CA (US); Tanya Dulkin, San Jose, CA (US); Raanan Y. Zehavi, San Jose, CA (US)

(73) Assignee: INTEGRATED PHOTOVOLTAIC, INC., San Jose, CA (US)

(21) Appl. No.: 13/010,700

(22) Filed: Jan. 20, 2011

Related U.S. Application Data
(60) Provisional application No. 61/296,799, filed on Jan. 20, 2010.

(51) Int. Cl. H01L 31/0368; H01L 31/18

(52) U.S. Cl. 136/258; 438/69; 257/E31.127

(57) ABSTRACT

A solar cell comprises a recrystallized active layer wherein the active layer has preferred characteristics.

### PRIORITY

This application claims priority from U.S. Provisional Application 61/296,799 filed on Jan. 20, 2010.

### CROSS-REFERENCE TO RELATED APPLICATIONS

This application is related in part to U.S. application Ser. Nos. 11/782,201, 12/074,651, 12/720,153, 12/749,160, 12/789,357, 12/860,048 and 12/860,088, all owned by the same assignee and incorporated by reference in their entirety herein. Additional technical explanation and background is cited in the referenced material.

### BACKGROUND OF THE INVENTION

1. Field of the Invention

The invention relates generally to preparation of silicon layers for use in a photovoltaic device.

2. Description of Related Art

Zone melt recrystallisation (ZMR) has been discussed and implemented in many applications requiring the formation of a high quality, low fault, crystal lattice after a material has been produced with substandard crystalline properties. Examples of this application are thin film depositions in solar cell fabrication or flat panel display devices. In both these cases, if the deposition is amorphous, there is a need to recrystallize the surface to achieve the required electrical properties of the device.

In bulk materials, float zone technology is very similar in method to achieve a similar result in which a narrow region of a crystal is molten, and this molten zone is moved along the crystal (in practice, the crystal is pulled through the heater). By controlling the speed of the bulk material through the molten area, crystal defects can repair themselves, or, impurities can be removed from the bulk material by being “pushed” forward by the melt zone.

The basic requirement of ZMR is to generate enough localized heat in order to melt a portion of the deposited material and to continue melting fresh material entering the zone as material leaving the zone solidifies and recrystallizes according to the crystalline structure of the material behind the melt zone, which acts as a seed. Common methods, well documented in the literature, used in solar applications use either a high power halogen lamp focused on the surface undergoing ZMR or a carbon strip heating element, heated by passing a high current through the strip, relying on the resistance of the carbon to generate heat. Both of these applications are capable of ZMR, but require significant control, and are not easily implemented in a manufacturing environment. Most systems in use are custom made by the end user, and each method has specific shortcomings. The halogen lamp systems are relatively unstable and difficult to control due to the natural fluctuations of the lamp filament and their relatively short lifetime. Additionally halogen lamp and carbon strip heating elements require significant base heaters to raise the overall temperature of the devices being processed to around 1000-1200° C. at which point, the ZMR is able to effectively recrystallize a layer of a few microns thickness, typically 2 to 5 μm.

Another common application is based on excimer lasers and is in use for thin film transistor (TFT) flat panel displays (FPDs). The deposition for TFT FPDs deposits a layer of amorphous silicon typically measured in nm as compared to an optimum layer thickness of approximately 30 microns in solar applications. In other words, the layers deposited in TFTs are 3-4 orders of magnitude thinner than the layers deposited in solar applications. Excimer laser recrystallisation, as performed for TFT applications result in crystal domains of approximately 0.1 micron. The crystal domains needed in solar applications in order to achieve the necessary electronic properties are of an order of mm to cm, a difference of 4 to 5 orders of magnitude. Excimer lasers are used in TFT applications because the energy is absorbed in the surface and does not propagate into the bulk of the material. For solar applications of ZMR the energy must propagate into the silicon layer. In other words ZMR implementation in solar applications is a volume process, significantly differentiating it from existing excimer laser based ZMR.

K. Yamamoto in “Thin film crystalline silicon solar cells”, JSAP International, No. 7, January 2003, points out desirable material characteristics for polycrystalline, thin film solar cells. For an open circuit voltage, Voc, above 500 mV grain size and carrier life time must be optimized; for instance at a grain size of about 0.1 micron, recombination velocity at grain boundaries must be less than 1,000 cm/s. Yamamoto points out several processing parameters that are beneficial for achieving these properties, namely, hydrogen passivation of the grains, low oxygen content and <110> orientation or at least preferred <110> orientation. Yamamoto is incorporated herein in its entirety by reference.

U.S. Pat. No. 7,645,337 discloses a complex method for providing polycrystalline films having a controlled microstructure; preferred orientation of a thin silicon film is achieved with complex optics and a precise laser pattern. Additional prior art is found in the following: U.S. Pat. No. 6,322,625; U.S. Pat. No. 6,326,215; U.S. Pat. No. 7,645,337; U.S.20080023070; U.S.20080202576; U.S.20080202577; U.S.20100132779; U.S.20100178435; U.S.20100190288; all incorporated herein in their entirety by reference.

### BRIEF SUMMARY OF THE INVENTION

One embodiment of the instant invention is based on a linear array of diode lasers working at 805 nm wavelength. An exemplary laser of this type is a Coherent 4000L diode laser. At 805 nm, almost 70% of the incident light is absorbed by silicon (at 600 microns thickness), the remaining 30% is reflected, as noted in FIG. 1.

A linear array of lasers may be imaged across the length of a surface being processed, which is typically 156 mm, ≈6 in., for standard pseudo square solar cells. This creates a narrow line or zone, approximately 1 mm wide, along one dimension of the solar cell. This heated zone melts the surface silicon deposited on the substrate and, optionally, capped by an oxide layer to prevent agglomeration of melted silicon into balls. The laser line, heating the zone, scans across the surface of the wafer, either using a slowly rotating mirror, a slow galvo controlled mirror, a robotic arm moving the entire laser head, or a motion control system moving the wafer underneath the laser line. By moving the laser beam relative to the surface at a rate of approximately 1 mm/sec the laser beam continues to melt all unmelted surface area entering the line scan or heated zone, while the surface exiting the heated zone solidifies and recrystallizes in alignment with the crystal lattice of the material behind the melt zone, optionally <100> or <110> or other orientation. In some embodiments a preferred recrystallization orientation is to the [100] plane, no seed crystal is required in the implementation of ZMR.

As the technology improves we might anticipate cell sizes to grow in much the same way that wafer sizes have grown in the IC industry. One of the advantages of linear arrays of laser diodes is the ability to increase the line length by adding additional diodes to the array. Laser ZMR can easily keep up with the growth of cell sizes.

### BRIEF DESCRIPTION OF THE SEVERAL VIEWS OF THE DRAWING(S)

FIG. 1 shows percent light adsorbed versus wavelength for a 600 micron layer.

FIG. 2 shows exemplary process steps for making a solar cell structure.

FIG. 3 shows exemplary layers of a solar cell structure.

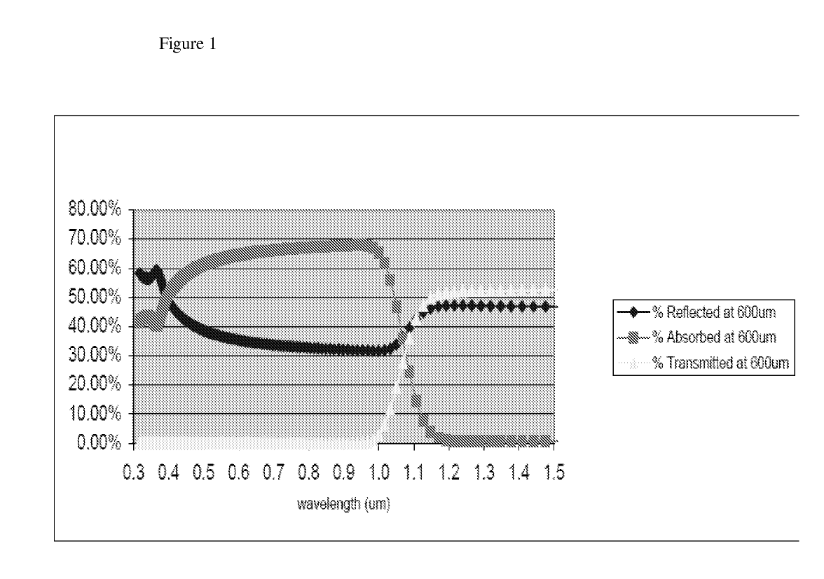

### DETAILED DESCRIPTION OF THE INVENTION

In another type of implementation, a focused spot may be scanned linearly across the surface being processed. This line may be generated by a rotating mirror or a galvo controlled mirror. The necessary optical system is implemented to keep the beam in focus at all points of the line. The energy of the beam is adjusted to result in a continuous melt of the surface layer in the area of the beam. As in the previous implementation discussed, the line may be moved relative to the surface at a rate of approximately 1 mm/sec; optionally, other scanning rates are feasible based on properties of a heating system and silicon material. Light beam(s) continue to melt all unmelted surface area entering the line scan, while the surface exiting the line scan solidifies and recrystallizes in alignment with the crystal lattice of the material behind the melt zone.

Another implementation of the method could generate the heating line by using appropriate cylindrical optics. Another implementation of the method could generate the line by using diffractive optics. Another implementation of the method could use a high temperature hot plate so that the surface being processed is elevated to a temperature close to the melting point of the material undergoing ZMR. This has the advantage of reducing the power requirements of the laser performing the ZMR, and, in some instances, reducing the thermal stresses generated by high temperature gradients in substrates. Use of a hot plate could result in less material losses due to stress related breakage.

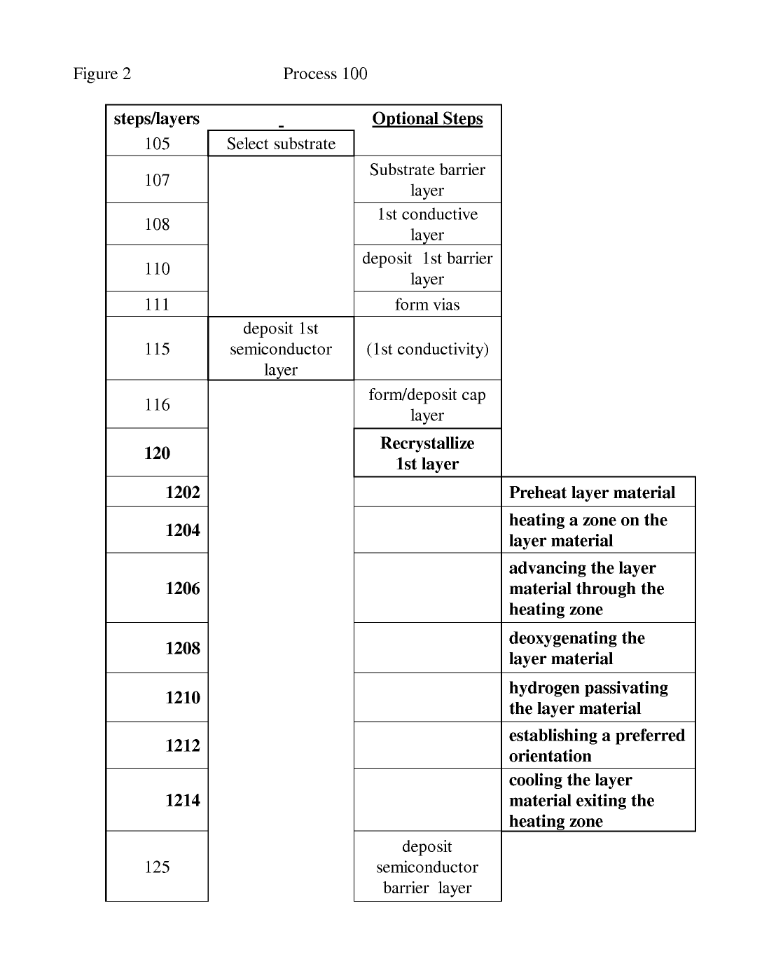

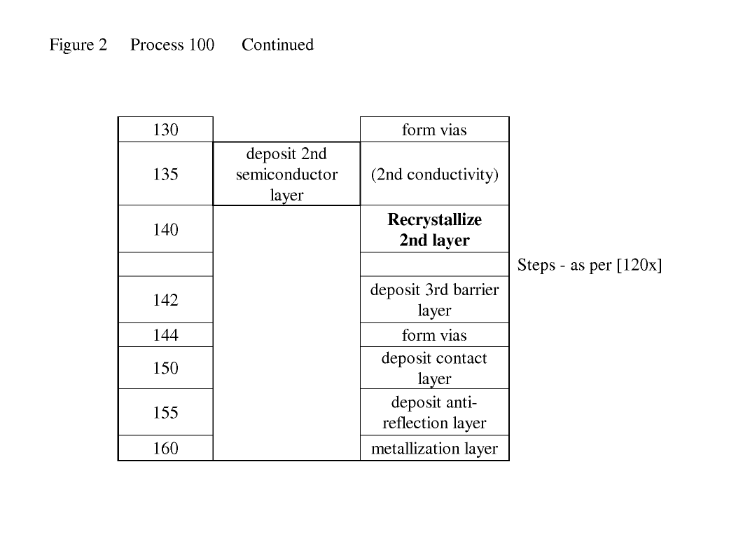

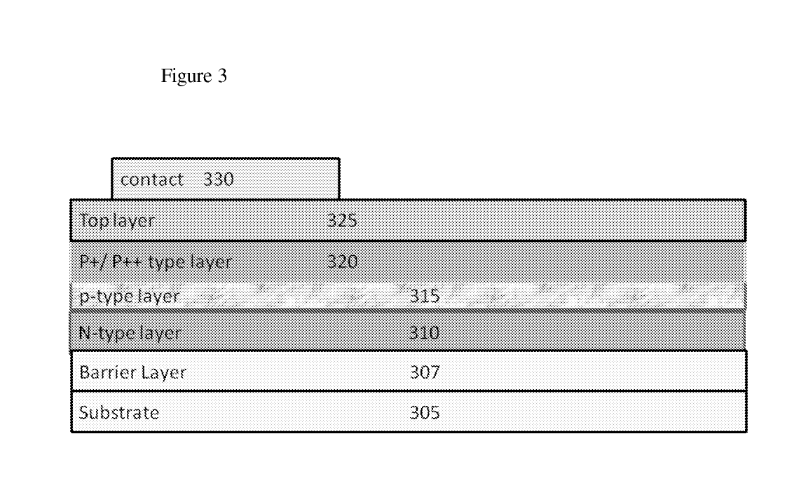

As shown in U.S. Ser. No. 12/860,088 and in FIGS. 2 and 3 herein, some embodiments comprise multiple layers and multiple process steps; some layers and steps are optional. FIG. 2 shows an exemplary embodiment of Process 100, comprising required steps 105 of selecting a substrate, 115, depositing a first semiconductor layer of first conductivity type; and 135 depositing a second semiconductor layer of second conductivity type. All other steps are optional and may or may not be used in any particular embodiment. For the instant invention at least one of the first or second semiconductor layers is recrystallized; steps 120 and 140 comprising steps 1202 through 1214 are steps available for recrystallization. Depending on the embodiment only steps 1204, 1206 and 1214 are required, the others being optional. Deoxygenating may be done with increased temperature in a low pressure environment or with a helium getter step; hydrogen passivating may be done with a hydrogen atmosphere at a temperature above about 800° C.; establishing a preferred orientation may be done with a seed crystal or selective texturing. As used herein an active layer comprises a first and second semiconductor layer of first and second conductivity types such that recombination of photons is enabled.

FIG. 3 shows an exemplary solar cell structure comprising elements of the instant invention. In some embodiments a solar cell may comprise one or more of the optional layers shown in FIG. 3. Required layers are a substrate, 305, first semiconductor layer of first conductivity type 310, optionally, a n-type layer and 2^{nd} semiconductor layer of second conductivity type 315, optionally a p-type layer; optional layers are a barrier layer 307, p+/p++ layer 320, top layer 325 and contact, as shown 330; a device will have a contact but it may be different than as shown in FIG. 3. In some embodiments a substrate may be a silicon substrate, a silicon composite comprising graphite, carbon or other combinations disclosed in the patents incorporated herein by reference. In some embodiments a first and second semiconductor layer thicknesses, individually, may be in the range of 100 nm to more than 10 microns.

In some embodiments a method of recrystallizing a solid layer of material comprises the steps: scanning the layer with a beam for heating such that a zone N mm wide across the entire layer is heated to a predetermined temperature; advancing the layer underneath the beam for heating at a rate of about M mm per second such that layer material entering the zone is at the predetermined temperature in less than one second and the layer material exiting the zone is more than 50° C. below the predetermined temperature in less than one second wherein the layer material leaving the zone solidifies into a predefined morphology; such morphology may be polycrystalline of random orientation or a preferred orientation; optionally, a method of recrystallizing wherein the beam for heating is a spot of radiation rapidly scanned over the zone such that more than 50% of the zone irradiated by the spot is equal to or greater than the predetermined temperature; optionally, a method of recrystallizing wherein the beam for heating is a linear array of radiation projected onto the zone such that at least 50% of the zone irradiated is equal to or greater than the predetermined temperature; optionally, a method of recrystallizing wherein the beam for heating is a spot of radiation projected onto the zone line image on the surface such that the surface illuminated by the line is in a continuously molten phase; optionally, a method of recrystallizing wherein the spot of radiation is generated by optics comprising a rapidly rotating mirror; optionally, a method of recrystallizing wherein the spot of radiation is generated by optics comprising a rapidly vibrating galvanometrically controlled; optionally, a method of recrystallizing wherein the line is imaged using cylindrical optics; optionally, a method of recrystallizing wherein the line is imaged using diffractive optics; optionally, a method of recrystallizing wherein the line is slowly scanned across the surface of the layer by using a slowly rotated mirror and appropriate optical system to maintain uniformity of beam size and energy density; optionally, a method of recrystallizing wherein the line is slowly scanned across the surface of the layer by using a galvanometrically controlled mirror and appropriate optical system to maintain uniformity of beam size and energy density; optionally, a method of recrystallizing wherein the line is slowly scanned across the surface of the layer by moving the beam with a robotic arm; optionally, a method of recrystallizing wherein the line is slowly scanned across the surface of the layer by slowly moving the layer under the line; optionally, a method of recrystallizing wherein the material being recrystallized is silicon; optionally, a method of recrystallizing wherein the material being recrystallized is not silicon; optionally, a method of recrystallizing wherein the layer material being recrystallized is the active layer of a solar; optionally, a method of recrystallizing wherein an additional heat source is used to increase the base temperature of the substrate in order to reduce the physical and thermal stress on the layer material in order to prevent breakage of the layer during zone melt recrystallization or after zone melt recrystallization; optionally, a method of recrystallizing wherein the base heater reaches a temperature just below the melting point of the layer being recrystallized; optionally, a method of recrystallizing wherein the entire system is enclosed in an environmentally controlled chamber to prevent undesired chemical changes in the materials being processed due to interactions with an uncontrolled environment at elevated temperatures. In some embodiments a heated zone may be as large as 3 mm or as small as 10 microns depending upon the substrate or laser beam advancing rate and the laser power density. Laser diodes are preferred at the higher power density. Advancing rates may range from 0.1 mm/sec to 10 mm/sec.

In some embodiments a solar cell comprises a substrate, optionally comprising graphite; an active layer comprising polycrystalline silicon wherein the active layer has been recrystallized such that the silicon grain size in the minimum dimension has a distribution between about 0.1 microns to about 100 microns wherein 10% or less of the grains have a size less than 1 micron and 10% or less of the grains have a size greater than 10 microns; optionally, a solar cell exhibits a recombination velocity between about 50 cm/s and about 500 cm/sec; optionally, a solar cell wherein the recombination velocity is less than about 100 cm/sec.; optionally, a solar cell wherein the grain boundaries have been hydrogen passivated; optionally, a solar cell wherein the oxygen content in the silicon active layer is less than 10¹⁶ at/cm³; optionally, a solar cell wherein the grains exhibit a preferred orientation along the <110> axis.

Combinations of high substrate advancing speed and high laser power enable rapid recrystallization. Rapid recrystallization is enabled by a smaller spot size achievable by a laser beam compared to other techniques, creating a higher power density and more efficient transfer of energy during a ZMR process. Although the current processes work with a laser beam traversing the wafer in the range of 1 mm/sec, there is little reason to prevent a laser based system to recrystallize at much higher velocities by increasing the laser power and providing a finer focus. A diffraction limited optical system for a laser diode array enables a line width below one mm and down to a few microns as required.

It will be understood that when an element as a layer, region or substrate is referred to as being “on” or “over” or “adjacent” another element, it can be directly on the other element or intervening elements may also be present. In contrast, when an element is referred to as being “directly on” or “directly over” or “in contact with” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

The foregoing described embodiments of the invention are provided as illustrations and descriptions. They are not intended to limit the invention to a precise form as described. In particular, it is contemplated that functional implementation of invention described herein may be implemented equivalently in various combinations or other functional components or building blocks. Other variations and embodiments are possible in light of above teachings to one knowledgeable in the art of semiconductors, thin film deposition techniques, and materials; it is thus intended that the scope of invention not be limited by this Detailed Description, but rather by Claims following.

We claim:

1. A method of recrystallizing a solid layer of material comprising the steps:
selecting a substrate;
depositing a first semiconductor layer of first conductivity type;
scanning the layer with a beam for heating such that a zone N mm wide across the entire layer is heated to a predetermined temperature;
advancing the layer underneath the beam for heating at a rate of about M mm per second such that layer material entering the zone is at the predetermined temperature in less than one second and the layer material exiting the zone is more than 50° C. below the predetermined temperature in less than one second after exiting the zone wherein the layer material leaving the zone solidifies into a predefined morphology.

2. The method of claim 1 wherein the beam for heating is a spot of radiation rapidly scanned over the zone such that more than 50% of the zone irradiated by the spot is equal to or greater than the predetermined temperature.

3. The method of claim 1 wherein the beam for heating is a linear array of radiation projected onto the zone such that at least 50% of the zone irradiated is equal to or greater than the predetermined temperature.

4. The method of claim 2 where the spot of radiation is generated by optics comprising a rapidly rotating mirror.

5. The method of claim 2 where the spot of radiation is generated by optics comprising a rapidly vibrating galvanometrically controlled mirror.

6. The method of claim 1 where the layer material is substantially silicon.

7. The method of claim 1 wherein the layer material being recrystallized is the active layer of a solar cell

8. The method of claim 1 comprising an initial step of heating a portion of the layer material to within 200° C. of the predetermined temperature before heating the zone.

9. The method of claim 1 comprising an initial step of heating a portion of the layer material to within 20° C. of the predetermined temperature before heating the zone and wherein the predetermined temperature is about 1420° C.

10. The method of 1 where the layer material is in an environmentally controlled chamber wherein the ambient temperature, pressure and gas composition is controlled to predetermined values and constituents.

11. The method of 1 where the heated zone width, N, is less than 100 microns wide.

12. The method of 1 where the layer advancing rate, M, is greater than about 1 mm per second.

13. A solar cell comprising;
a substrate;
a first semiconductor layer comprising polycrystalline silicon of first conductivity type wherein the first semiconductor layer has been recrystallized by the method of claim 1 such that the silicon grain size in the minimum dimension has a distribution between about 0.1 microns to about 100 microns wherein 10% or less of the grains have a size less than 1 micron and 10% or less of the grains have a size greater than 10 microns.

14. A solar cell of claim 13 wherein the recombination velocity is between about 50 cm/s and about 500 cm/sec.

15. A solar cell of claim 13 wherein the recombination velocity is less than about 100 cm/sec.

16. A solar cell of claim 13 wherein the grain boundaries have been hydrogen passivated.

17. A solar cell of claim 13 wherein the oxygen content in the silicon active layer is less than about 10¹⁸ at/cm³.

18. A solar cell of claim 13 wherein the grains exhibit a preferred orientation along the <110> or <100> axis.

19. A solar cell of claim 13 wherein the substrate is chosen from a group consisting of silicon, silicon composite with graphite, and carbon.

20. A solar cell of claim 13 further comprising a barrier layer.
